(19) United States
(12) Patent Application Publication
(10) Pub. No.: US 2025/0239495 A1
(43) Pub. Date: Jul. 24, 2025

(54) SEMICONDUCTOR DIE AND WAFER BONDING CRACK DETECTOR STRUCTURES AND METHODS OF FORMING SAME

(71) Applicant: Taiwan Semiconductor Manufacturing Company LTD, Hsinchu (TW)

(72) Inventors: Ming Jun Li, New Taipei (TW); Chi-Hui Lai, Taichung (TW); Yang-Che Chen, Hsinchu (TW); Hsiang-Tai Lu, Zhubei (TW); Wei-Ray Lin, Hsinchu (TW)

(21) Appl. No.: 18/421,026

(22) Filed: Jan. 24, 2024

(51) Int. Cl. H01L 21/66; G01R 31/26; H01L 23/00

(52) U.S. Cl. CPC H01L 22/32; G01R 31/2601; H01L 24/06; H01L 24/08; H10D 1/714; H01L 2224/06515; H01L 2224/08145

(57) ABSTRACT

A semiconductor structure includes: a first semiconductor die or wafer including a first bonding crack detection structure portion including discrete bonding crack detection structure portions that are electrically isolated, and a second semiconductor die or wafer bonded to the first semiconductor die, the second semiconductor die or wafer including a second bonding crack detection structure portion including discrete bonding crack detection structure portions that are electrically isolated, wherein the first bonding crack detection structure portion and the second bonding crack detection structure portion are bonded together to form a bonding crack detection structure.

### BACKGROUND

The following relates to semiconductor devices, to die and wafer bond interface crack detectors and methods of forming the same, and the like.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B illustrate a semiconductor die stack including a hybrid bonding crack according to an example embodiment of the present disclosure.

FIGS. 2A-2C illustrate a semiconductor die stack including a bonding crack detection structure according to an example embodiment of the present disclosure (Embodiment 3) FIG. 2A is a perspective view, FIG. 2B is a top view and FIG. 2C is a cross sectional view.

FIGS. 3A-3C illustrate various operational details of a bonding crack detection structure according to an example embodiment of the present disclosure.

FIG. 4 illustrates a bonding crack detection system according to an example embodiment of the present disclosure, the system including a bonding crack detection structure and a leakage current detector E-test (Electrical-test) device used for I-V (current-voltage) measurement of leakage current representative of a bonding interface crack.

FIGS. 5A and 5B illustrate further details of a semiconductor die stack including a bonding crack detection structure 2001 according to an example embodiment of the present disclosure (Embodiment 1).

FIGS. 6A and 6B illustrate further details of a semiconductor die stack including a bonding crack detection structure 2002 according to an example embodiment of the present disclosure (Embodiment 2).

FIGS. 7A and 7B illustrates another semiconductor die stack including a bonding crack detection structure 2003 according to an example embodiment of the present disclosure (Embodiment 3).

FIGS. 8A-8C illustrate further operational and design details associated with a bonding crack detection structure according to example embodiments of the present disclosure.

FIG. 9A illustrates a plurality of bonding crack detection structures integrated into a SoC (System on a Chip) package according to an example embodiment of the present disclosure, and FIG. 9B illustrates a plurality of bonding crack detection structures integrated into a wafer, the wafer including multiple SoCs according to an example embodiment of the present disclosure.

FIG. 10 illustrates a process for fabricating a semiconductor die stack including multiple bonding crack detection structures according to an example embodiment of the present disclosure.

FIG. 11 illustrates a process for fabricating a semiconductor wafer stack including multiple bonding crack detection structures according to an example embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “top”, bottom”, “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “layer”, as used herein, may include a single layers or multiple layers.

The term “intermetal dielectric” (IMD) film or layer, as used herein, refers to a dielectric/insulation material(s) layer between two metal or other electrically conductive layers. IMD material may, by way of some nonlimiting illustrative examples, comprise polysilicon, silicon oxide, silicon nitride, silicon oxynitride, phosphosilicate glass (PSG), borophosphosilicate glass (BPSG), spin-on glass (SOG), fluoride-doped silicate glass (FSG), carbon doped silicon oxide (SiCOH), polyimide, amorphous fluorinated carbon, bis-benzocyclobutenes (BCB), hydrogen silsesquioxane, fluorinated silicon oxide (SiOF), and/or combinations thereof.

The term “interlayer dielectric” (ILD) layer, as used herein, refers to an insulating structure of material(s) placed between two conductive layers. An ILD layer may, by way of some nonlimiting illustrative examples, comprise polysilicon, silicon oxide, silicon nitride, silicon oxynitride, phosphosilicate glass (PSG), borophosphosilicate glass (BPSG), spin-on glass (SOG), fluoride-doped silicate glass (FSG), carbon doped silicon oxide (SiCOH), polyimide, amorphous fluorinated carbon, bis-benzocyclobutenes (BCB), hydrogen silsesquioxane, fluorinated silicon oxide (SiOF), and/or combinations thereof.

The term “hybrid bonding” as used herein refers to the simultaneous bonding of dielectric and metal bond pads in one bonding step, where the semiconductor dies and/or semiconductor wafer stacks are bonded with an interface such as a metal and oxide interface. Hybrid bonding is a permanent bond that, in some embodiments, combines a dielectric bond (e.g. SiOₓ) with an embedded metal (e.g. Cu) to form interconnections. Hybrid bonding, in some embodiments, extends fusion bonding with embedded metal pads in the bond interface, which allows face-to-face connection of the dies and wafers.

The terms “bonding pad”, “bonding pad structure”, “hybrid bonding pad”, “metal bonding bumps” are used interchangeably and refer to a metal bonding pad connected to a bonding pad via. A metal as used herein may comprise an elemental metal (e.g., copper, aluminum), a metal alloy, or another suitably electrically conductive material such as titanium nitride or tantalum nitride.

The term “bonding crack detection structure” as used herein refers to a structure integrated or incorporated into a semiconductor structure for the detection of cracks within the semiconductor structure. Alternatively, a “bonding crack detection structure” may also be referred to, and includes, a “bonding crack detection sensor” used to detect cracks within semiconductor structure.

The term “metallization layer”, and “conductor” as used herein to describe the bonding crack detection structure disclosed herein, includes a conductor, layer, trace or track, made of copper, aluminum (Al), and other electrically conductive metals.

In some embodiments, a bonding crack detection structure for testing for cracks in a bond between a first semiconductor wafer or die and a second semiconductor wafer or die is constructed as follows. A first conductor of the bonding crack detection structure includes a first set of metal bonding bumps disposed on the first semiconductor wafer or die and a third set of metal bonding bumps disposed on the second semiconductor wafer or die, and which are bonded with the first set of metal bonding bumps of the first semiconductor wafer or die. A second conductor of the bonding crack detection structure includes a second set of metal bonding bumps disposed on the first semiconductor wafer or die and a fourth set of metal bonding bumps disposed on the second semiconductor wafer or die, which are bonded with the second set of metal bonding bumps of the first semiconductor wafer or die. The first conductor and the second conductor constitute a capacitor structure, and the first conductor and the second conductor are electrically isolated from each other in the absence of a bonding crack. Hence, an electrical bias applied between the first and second conductors should produce a low (ideally zero) electrical current. However, in the presence of a bonding crack, the electrical isolation between the first conductor and the second conductor is compromised, and a larger electrical current will be measured, thus indicating the crack. If water ingress has occurred at the interface due to the crack (which in this example could be an incomplete or non-hermetically sealed bond between the wafers) then this also will be detected as an enhanced measured electrical current. Hence, the disclosed bonding crack detection structure provides for convenient electrical testing for cracks. While measurement of electrical current in response to an applied voltage is a convenient measurement, other electrical characteristics of the capacitive bonding crack detection structure can be measured, such as electrical resistance. Also, since the crack should pass through or otherwise impinge upon the bonding crack detection structure in order to be detected, in some embodiments the bonding crack detection structure is designed to have an increased overall area.

This disclosure provides a semiconductor die and wafer bonding interface/crack detection test structure and system for detecting semiconductor die and wafer bonding interface cracks. According to an example embodiment, the disclosed semiconductor die and wafer test structure and system is used to detect bonding interface cracks by measuring for leakage current, representative of a bonding interface crack, during the processing of the die and/or wafer. Alternatively, an electrical resistance of the bonding crack detection structure can be measured to determine a bonding interface crack. The disclosed bonding interface test structure can be E-tested as part of a testing phase associated with one or more of the WAT/WLCP/FT (Wafer Acceptance Test/Wafer Level Chip Package/Final Test) phases. Some example applicable fields include 3DIC products formed using hybrid bond interfaces to stack and attach semiconductor dies and wafers.

According to some embodiments disclosed herein, the following provides a bonding film crack detection structure for incorporation into a semiconductor stacked die and/or semiconductor stacked wafer arrangement. Bonding interface cracking, such as bonding film cracking, can occur during the fabrication of stacked semiconductor dies and/or wafers. For purposes of this disclosure, bonding interface cracking, and the detection thereof, is described in the context of a hybrid bonding process, which can include the simultaneous bonding of dielectric and metal bond pads in one bonding step, where the semiconductor dies and semiconductor wafer stacks are bonded with a metal and oxide interface. However, the disclosed crack detection structures are not limited to hybrid bonding.

Bonding interface cracks can induce the mechanical breaking of metal traces which results in electrical shunt or open electrical connection failures of a semiconductor device. In addition, a relatively large bonding interface crack can result in metal-to-metal leakage if moisture penetrates a chip through bonding interface crack. Traditional methods to identify bonding interface cracks usually only occur after the crack results in a catastrophic failure, such as an open electrical connection or conductor associated with a tested chip during the fabrication process. Some methods to identify a bonding interface crack include using a scanning electron microscope (SEM) or IR to analyze a cross section portion of the chip to confirm the existence of a bonding interface crack. This failure testing and analysis usually occurs late in a package assembly process or reliability test, and so the initial bonding interface crack cannot be identified in the early stages of the process. Disclosed herein is a bonding interface crack detection structure and E-test structure to detect bonding interface cracks, such as a hybrid bonding interface crack, during one or more semiconductor chip fabrication processes.

According to an example embodiment of the disclosed bonding interface crack detector structure, an interdigitated comb finger metal-oxide-metal (MOM) capacitor structure is formed by BEOL (back end of line) metals and hybrid bonding metal. To boost bonding interface crack detection sensitivity, the crack detection structure utilizes hybrid bond metal layers (metal and VIA in both top and bottom dies or wafers) to form relatively thick capacitor sidewalls. These thick sidewalls introduce more crack detection area for leakage current testing using an I-V E-testing unit. The bonding interface crack test structure is partially formed by the top die and partially formed by the bottom die for a stacked and bonded die arrangement, where the bonding interface crack detection structure is embedded into the bonding interface near likely crack locations, thereby increasing the likelihood that a bonding interface failure is detected.

Some features and benefits of the disclosed bonding interface structure and E-test structure the electrical testing for hybrid bonding cracks which does not require the use of time-consuming physical failure analysis (PFA) which, as a practical matter, cannot be performed on every semiconductor die, wafer and/or chip. Other advantages may include: 1) a relatively fast and simple electrical current leakage test (leakage being indicative of a crack) performed by I-V measurements; 2) bonding crack detection, or lack thereof, is able to be detected during one or more of several fabrication stages, e.g. WAT/WLCP/FT, so when a bonding interface crack occurs it can be identified by a step-by-step process to locate the appropriate fabrication process step to improve/correct the cause of the detected bonding interface crack(s); 3) the bonding interface test structure requires only a relatively small area, as compared to the overall size of the semiconductor dies and wafers of which it is included, which allows the disclosed bonding interface test structure to be placed in scribe line for testing during the WAT phase; and 4) the relatively small size of the bonding interface crack detection structure enables the location of the crack detection structure to be located in a die or chip corner which is a high risk location for crack formation.

The detailed description that follows will primarily describe the disclosed bonding interface crack detection structures, and methods of forming the same, integrated into a top semiconductor die portion(s) and a bottom semiconductor die portion(s), the top and bottom semiconductor dies subsequently hybrid bonding to form a complete bonding interface crack detection structure(s). However, the disclosed bonding interface crack detection structures, and methods of forming the same, can also be integrated into a top semiconductor wafer portion(s) and a bottom semiconductor wafer portion(s), the top and bottom semiconductor wafers subsequently hybrid bonding to form a complete bonding interface crack detection structure(s).

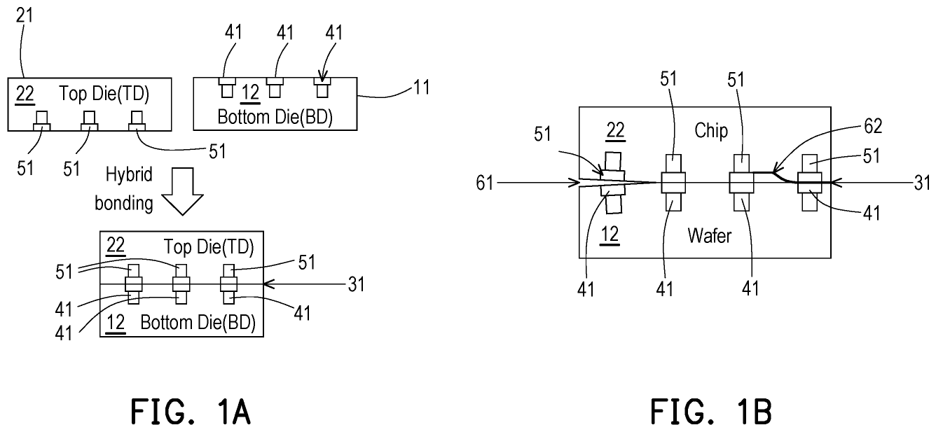

Referring to FIGS. 1A and 1B, provided now is more detail describing the formation of a bonding crack formed during the hybrid bonding of a top semiconductor die 21 (or wafer) and a bottom semiconductor die 11 (or wafer), as well as the use of the bonding crack for testing of leakage current as will be described throughout this disclosure. As shown, initially the bottom semiconductor die 11 of a stack is fabricated to include metal bonding pads 41, and the top semiconductor die 21 is fabricated to include metal bonding pads 51. The metal bonding pads 41 and 51 are bonded, e.g. fused, during the die bonding process to form a hybrid bonding of the bottom and top semiconductor dies. The hybrid bonding process also includes a dielectric bonding (IMD 12 and IMD 22) of the semiconductor dies at the bonding interface 31.

Referring now to FIGS. 1B, and as previously discussed, during the fabrication process, bonding interface 31 cracks 62 can develop which are a result of a nonbonded and delaminated area of the bonding interface 31. As shown, a failure of the die results from nonelectrical contact of one or more of any metal bonding metal pads 41 and 51 which are not in electrical contact, i.e. not fused.

As a result of the delamination and nonbonding area 61 of the semiconductor stack shown in FIG. 1B, moisture penetrates the bonding interface crack 62 as the crack is formed during the bonding process of the bottom semiconductor die 12 and the top semiconductor die 22. This disclosure, and the example embodiments described herein, utilizes the crack moisture for testing of leakage current between one or more of the metal bonding pads by applying a high/low voltage potential to normally electrically isolated metal bonding pads. In the event there is leakage current from one metal bonding pad to another normally electrically isolated bonding pad, then the leakage current is a result of a bonding interface crack 51 and the conductive moisture contained therein. In this regard, it may be noted that a crack may form at the time of the bonding, or may form during a later fabrication process, such as a subsequent process that involves heating the bonded stack of wafers where the heat can induce delamination. Advantageously, the E-test disclosed herein can be repeated at multiple points during the fabrication process to detect initial or later-induced cracking.

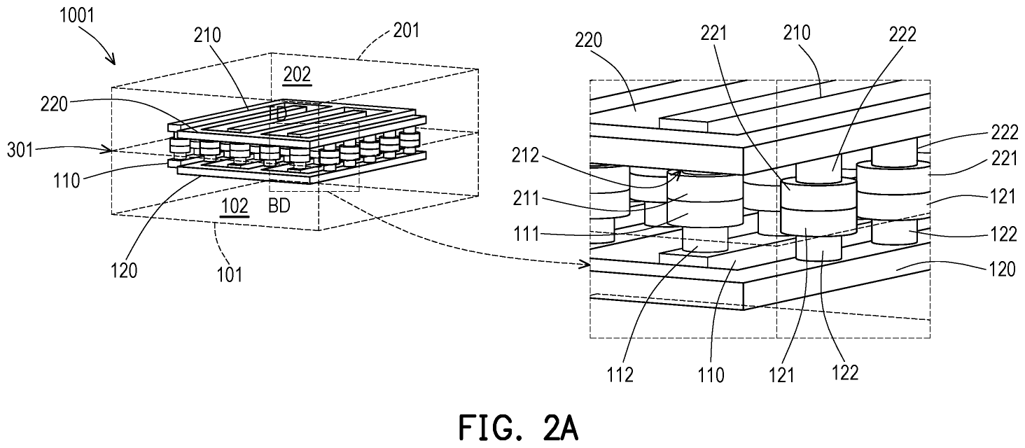

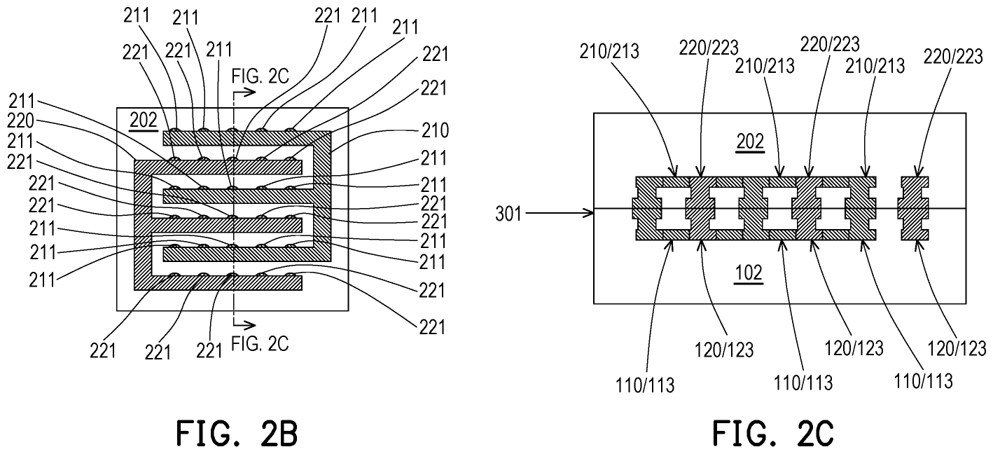

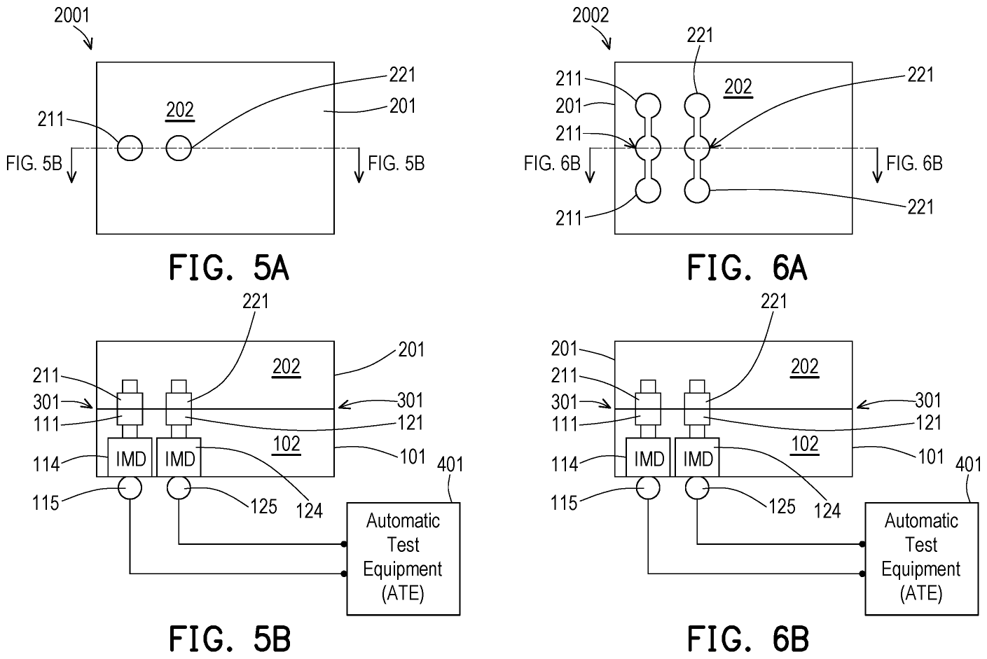

Referring now to FIGS. 2A-2C, shown is a semiconductor die stack including a bonding crack detection structure 1001, including an interdigitated MOM capacitor structure, according to an example embodiment of the present disclosure. (Embodiment 3). Embodiments 1 and 2 are described below with reference to FIGS. 5A and 5B (Embodiment 1) and FIGS. 6A and 6B (Embodiment 2).

As shown in FIGS. 2A-2C, the bonding interface crack detection structure includes a first, or bottom, semiconductor die 101 including a first bonding crack detection structure portion formed in an IMD layer 102 and a second, or top, semiconductor die 201 including a second bonding crack detection structure portion formed in an IMD layer 202. The top semiconductor die 201 and bottom semiconductor die 101 are hybrid bonded together to form a stacked die arrangement, where the top semiconductor die 201 bonding crack detection structure portion is bonded to the bottom semiconductor die bonding crack detection structure portion. Not shown in FIGS. 2A-2C is the inclusion of one or more functional circuits (e.g., comprising MOSFETs, diodes, and/or other semiconductor devices) formed on the top semiconductor die 101, and/or on the bottom semiconductor die 201, which provide functional features of the completed chip. The bonding crack detection structure(s) disclosed and described herein are electrically isolated from any functional circuits included on the semiconductor dies or wafers. However, it is within the scope of this disclosure that the bonding crack detection structure(s) may potentially be integrated within the functional circuits, depending on the design of the functional circuits.

Referring again to FIGS. 2A-2C, the bottom semiconductor die 101 bonding crack detection structure portion includes a first set of metal bond pads 111 operatively connected to a bonding interface 301 side of the bottom semiconductor die, and a second set of metal bond pads 121, parallel and laterally offset from the first set of metal bonding pads 111. The second set of metal bond pads 121 are operatively connected to the bonding interface 301 side of the bottom semiconductor die, and the second set of metal bond pads are electrically isolated from the first set of metal bond pads by IMD material 102 which acts as an insulator within the gap or lateral offset between the first set of metal bonding pads 111 and the second set of metal bonding pads 121. The top semiconductor die 201 bonding crack detection structure portion includes a third set of metal bond pads 211 operatively connected to a bonding interface 301 side of the top semiconductor die, and a fourth set of metal bond pads 221, parallel and laterally offset from the third set of metal bonding pads 211. The fourth set of metal bonding pads 221 are operatively connected to the bonding interface 301 side of the top semiconductor die 201, and the fourth set of metal bond pads 221 are electrically isolated from the third set of metal bond pads 211 by IMD material 202 which acts as an insulator within the gap or lateral offset between the third set of metal bonding pads 211 and the fourth set of metal bonding pads 221.

The bottom bonding crack detection structure portion (bonding metal pad sets 111 and 121) and the second bonding crack detection structure portion (bonding pad sets 211 and 221) are bonded together to form a bonding crack detection structure in which the first set of metal bond pads 111 and the third set of metal bond pads 211 are electrically connected together to form conductor A (conductor 110 electrically connected to conductor 210), and the second set of metal bond pads 121 and the fourth set of metal bond pads 221 are electrically connected together to form conductor B (conductor 120 electrically connected to conductor 220). In addition, after bonding, the first set of metal bond pads 111 and bonded/electrically connected third set of metal bond pads 211 are electrically isolated from the second set of metal bond pads 121 and bonded/electrically connected fourth set of metal bond pads 221.

Further details of the bonding crack detection structure shown in FIGS. 2A-2C include the inclusion of vias (e.g., tungsten vias or vias of another electrically conductive material) formed in the bottom semiconductor die 101 and top semiconductor die 202. These vias are formed in IMD layers 102 and 202, and provide electrical connections of bonding metal pads to a connecting conductor 220 or metallization layer that includes traces or tracks that electrically interconnect bonding metal pads to form chains or segmented portions of the bonding crack detection structure. As shown in FIGS. 2A-2C, these conductive chains or segments are arranged as a plurality of fingers that are interdigitated to provide an interdigitated MOM capacitive structure.

More specifically, the bonded and completed bond crack detection structure includes a bottom semiconductor die crack detection portion including two electrically isolated conductor portions or legs A 110 and B 120, the conductor A portion 110 including bonding metal pads 111 electrically connected to conductor 113 with bonding metal pad vias 112, and the conductor B portion 120 including bonding metal pads 121 electrically connected to conductor 123 with bonding metal pad vias 122. The bonded and completed bond crack detection structure also includes a top semiconductor die crack detection portion including two electrically isolated conductor portions or legs A 210 and B 220, the conductor A portion 210 including bonding metal pads 211 electrically connected to conductor 213 with bonding metal pad vias 212, and the conductor B portion 220 including bonding metal pads 221 electrically connected to conductor 223 with bonding metal pad vias 222.

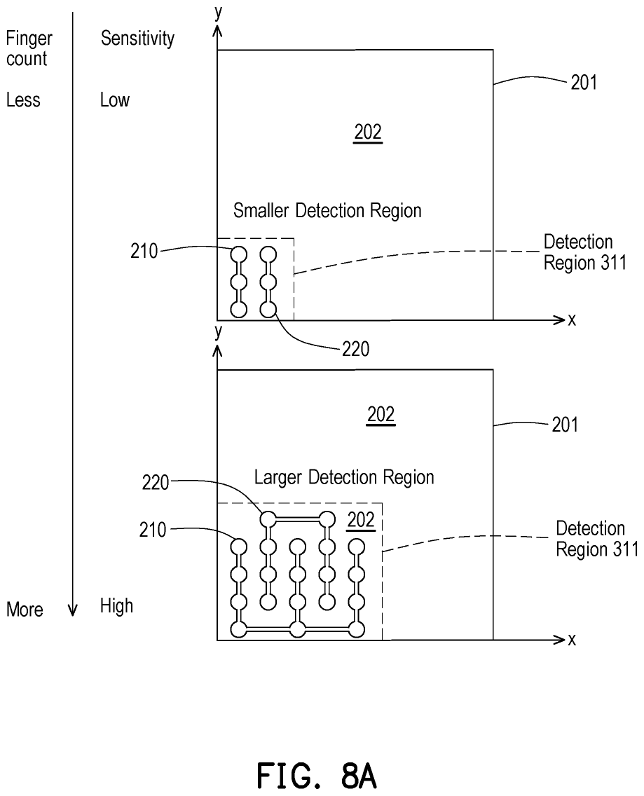

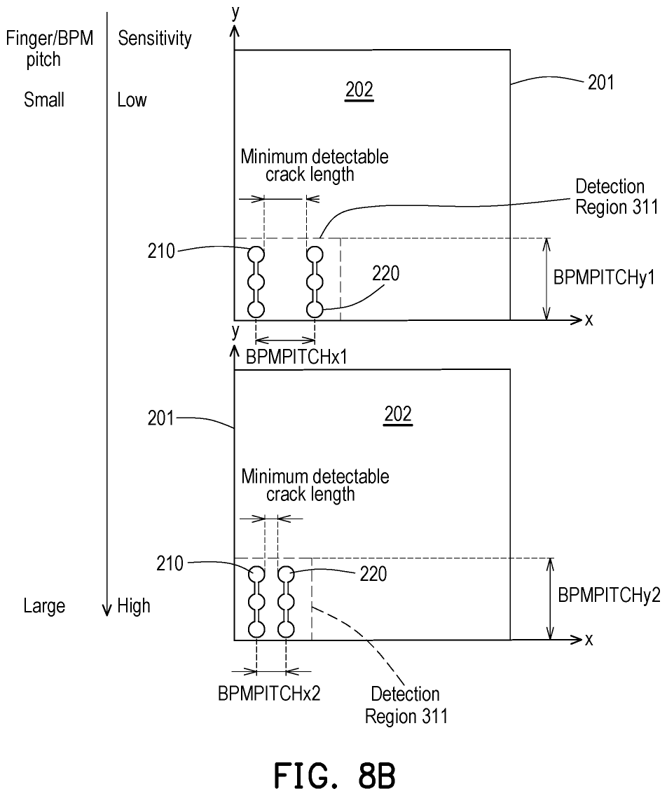

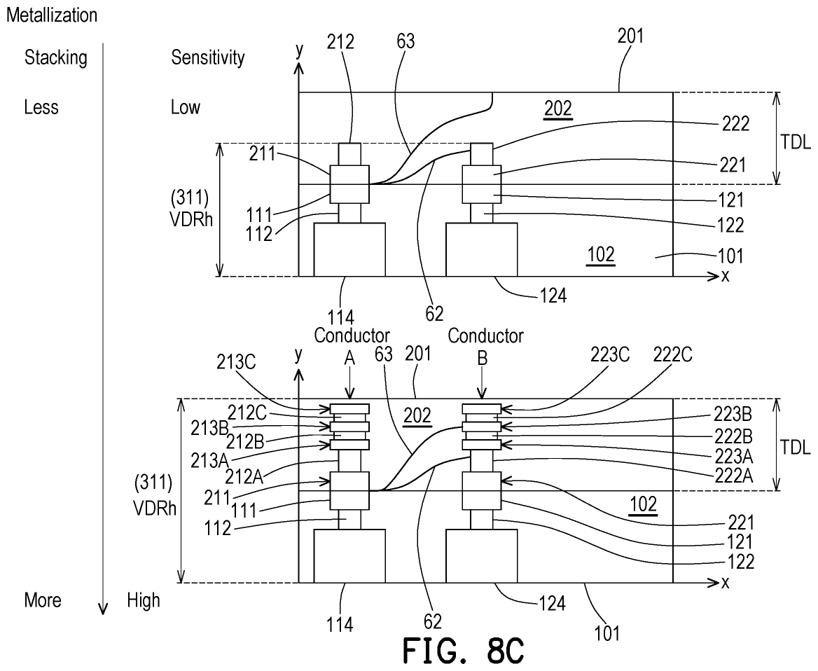

As will be more fully described below with reference to FIGS. 8A-8C, the sensitivity of the disclosed bonding crack detection structure is affected by factors including, but not limited to, the following:
1) metal bonding pad count (BPM count), where the higher the BPM count, the greater the crack detection sensitivity/accuracy of the bonding crack detection structure to detect bonding cracks present in the bonding interface;
2) pitch, or spacing, of the metal bonding pads (BPM Pitch), where the lower the BPM pitch, the greater the crack detection sensitivity of the bonding crack detection structure to detect bonding cracks present in the bonding interface;
3) finger counts (FC), where the higher the FC the greater the crack detection sensitivity of the bonding crack detection to detect bonding cracks present in the bonding interface; and
4) routing layer count (RLC), where the routing layers (e.g. vias 213 and 223) can be extended to provide a multiple tiered interdigitated MOM capacitor arrangement including multiple stacked conductor portions (e.g. conductor A 210 and conductor B 220). This stacked multiple tier arrangement extends the vertical crack detection region up to the height of the IMD (e.g. IMD 202), thereby providing complete vertical crack detection for the height of the IMD layer.

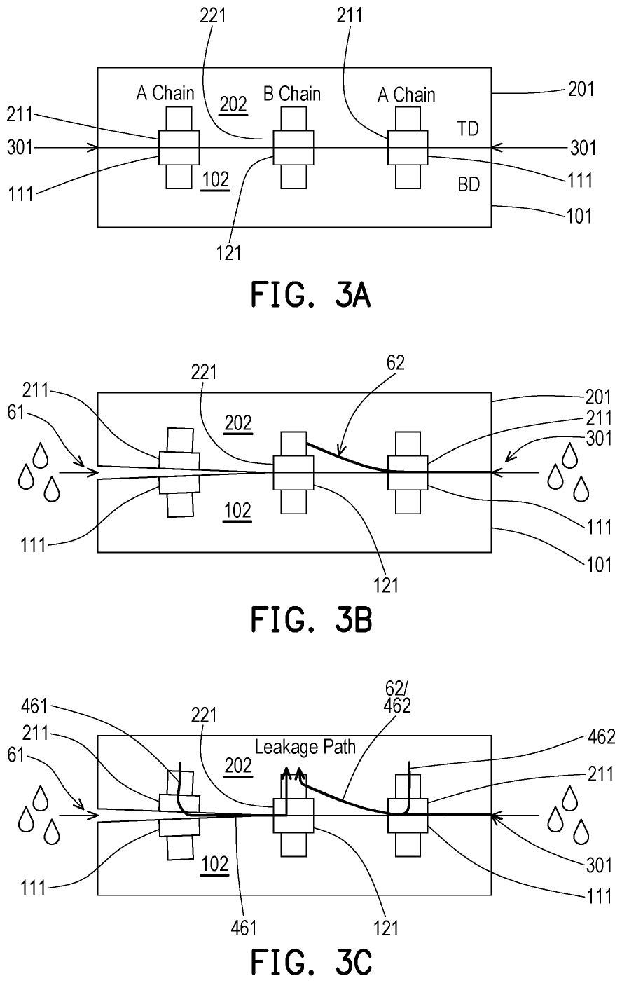

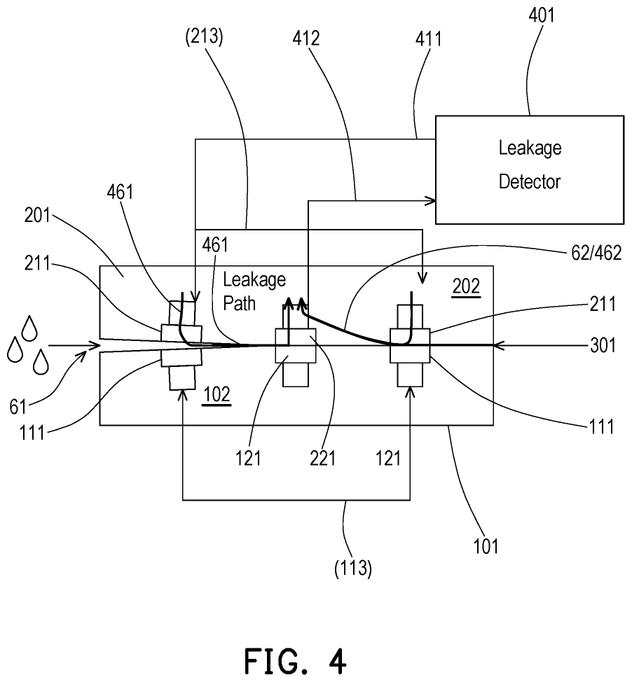

Referring to FIGS. 3A-3C, and FIG. 4, illustrated are various operational details of a bond crack detection structure according to an example embodiment of the present disclosure (Embodiment 2), which also applies to the other embodiments described herein. Specifically, FIGS. 3A-3C illustrate the flow of current through a leakage current path present within a bond crack detection structure as disclosed herein.

Referring to FIG. 3A, illustrated is a stacked and bonded semiconductor die arrangement 101 and 201 which does not include any bonding interface cracks. In other words, FIG. 3A shows an acceptable bonded pair of semiconductor dies without any cracks. The bonding crack detection structure, as previously described with reference to FIGS. 2A-2C, the bottom semiconductor die 101 includes a first chain of electrically connected metal bonding pads 111 and a second chain of electrically connected metal bonding pads 121, the second chain of electrically connected metal bonding pads 121 electrically isolated from the first chain of electrically connected metal bonding pads 111. The top semiconductor die 201 includes a third chain of electrically connected metal bonding pads 211 and a fourth chain of electrically connected metal bonding pads 221, the fourth chain of electrically connected metal bonding pads 221 electrically isolated from the third chain of electrically connected metal bonding pads 211. As previously described, the bottom bonding crack detection structure portion (bonding metal pad sets 111 and 121) and the second bonding crack detection structure portion (bonding pad sets 211 and 221) are bonded together to form a bonding crack detection structure in which the first set of metal bond pads 111 and the third set of metal bond pads 211 are electrically connected together to form conductor A, and the second set of metal bond pads 121 and the fourth set of metal bond pads 221 are electrically connected together to form conductor B. In addition, after bonding, the first set of metal bond pads 111 and bonded/electrically connected third set of metal bond pads 211 are electrically isolated from the second set of metal bond pads 121 and bonded/electrically connected fourth set of metal bond pads 221.

Referring to FIG. 3B, illustrated is a stacked and bonded semiconductor die arrangement 101 and 201 which does include a bonding interface crack 62, resulting from fabrication inconsistencies which resulted in a nonbonded and delaminated region of the bond interface. In other words, FIG. 3B shows a nonacceptable bonded pair of semiconductor dies which includes a crack and is rejected for any further fabrication processing. As shown, moisture during the bonding process enters the nonbonded and delaminated region 61 of the interface region 301 and permeates into crack 62. The moisture contained with the nonbonded region 61 and crack 301 provides an electrical current paths 461 and 462, for an I-V source, (not shown) from metal bonding pad 211 to metal bonding pad 221, which would normally be electrically isolated if there was not a crack 62 and nonbonded area 61.

Referring to FIG. 4, illustrated is a bond crack detection E-test system for measuring leakage current resulting from a nonbonded/delaminated region and bonding crack as described above with reference to FIG. 3C, according to an example embodiment of the present disclosure, The E-test system includes a bond crack detection structure as shown in FIGS. 3A-3C, with the addition of schematical representations of the electrical connection 113 of bottom semiconductor die metal bonding pads 111, the electrical connection 213 of top semiconductor die metal bonding pads 211.

A leakage current detector 401 generates a voltage differential where a first potential (e.g. positive) 411 is applied to metal bonding pads 111 and 211, and a second (e.g. negative) potential 412 is applied to metal bonding pads 121 and 221. As can be seen FIG. 4, the voltage differential provides a leakage current paths 461 and 462 from metal bonding pads 211 to metal bonding pad 221, which would normally be electrically isolated if there was not a crack 62 and nonbonded area 61. For the case shown in FIG. 4, the nonbonded delaminated region 61 (or water ingress at that delaminated region 61) results in leakage current 461, the bonding crack 62 results in leakage current 462. The leakage current detector 401 monitors supplied by the leakage current detector E-test unit 401 and in the event a leakage current is detected above a threshold, e.g. 80 pA, an output of the unit 401 notifies the appropriate system that a failure detection has been detected. Indeed, in test runs it was found that the disclosed capacitive bonding crack detection structure provides a large difference in measured current between passing (no crack) examples for which the measured electrical current was under 100 picoamperes, versus examples where a crack was present for which much larger electrical current was measured on the order of 1 microampere or larger. In some such tests, a difference in measured current magnitude of greater than 10,000 was observed for crack versus no crack test runs.

Notably, the E-test can be performed using DC (direct current), enabling simplification of the current detector 401. (However, AC (alternating current) testing is also contemplated). According to another example embodiment, the E-test system measures the resistance of the bond crack detection structure, where a resistance below a threshold value indicates a bonding interface crack.

Referring to FIGS. 5A-5B, illustrated is another example embodiment of a semiconductor die stack including a bond crack detection structure according to an example embodiment of the present disclosure (Embodiment 1). FIG. 5A is a top view and FIG. 5B is a cross sectional view. According to this example embodiment, the bond crack detection structure includes single metal bond pad pair 111 and 211 which provide conductor A, and metal bond pair 121 and 221 which provide conductor B. Crack detection is limited to the area of the IMD layers 102 and 202 between conductors A (121 and 221) and conductor B (102 and 202). This embodiment does not include chains of metal bonding pads as previously discussed with reference to FIGS. 2A=2C. Automated Test Equipment (ATE) 401 provides automated V-I testing of the semiconductor stacked and bonded structure to determine if any bonding interface cracks exist. Independent IMD layer 114 and first level interconnect 115, and IMD layer 124 and first level interconnect 125 provide external electrical connections of the bond crack detection structure to the ATE 401.

Referring to FIGS. 6A and 6B, illustrated is another example embodiment of a semiconductor die stack including a bond crack detection structure according to an example embodiment of the present disclosure (Embodiment 2). FIG. 6A is a top view and FIG. 6B is a cross sectional view. According to this example embodiment, the bond crack detection structure includes a chain of metal bond pad pairs 111 and 211 which provide conductor A, and a chain of metal bond pairs 121 and 221 which provide conductor B. Crack detection is limited to the area of the IMD layers 102 and 202 between conductors A (121 and 221) and conductor B (102 and 202). This embodiment does include chains of metal bonding pads as previously discussed with reference to FIGS. 2A=2C, however this embodiment does not include interdigitated fingers as described with reference to FIGS. 2A-2C. Automated Test Equipment (ATE) 401 provides automated V-I testing of the semiconductor stacked and bonded structure to determine if any bonding interface cracks exist. Independent IMD layer 114 and first level interconnect 115, and IMD layer 124 and first level interconnect 125 provide external electrical connections of the bond crack detection structure to the ATE 401.

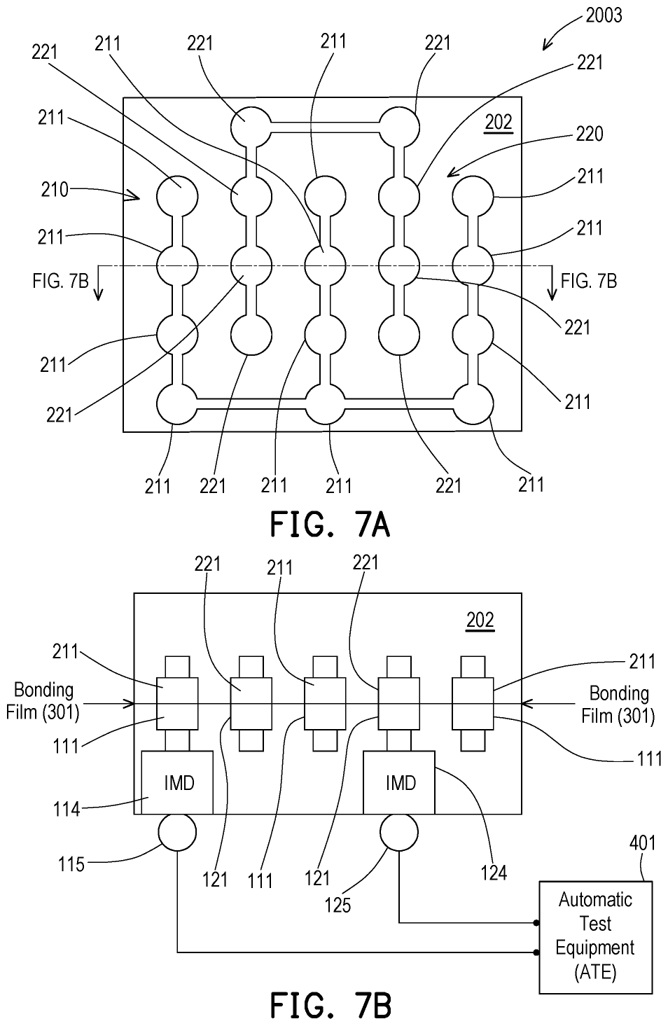

Referring to FIGS. 7A-7B, illustrated is another example embodiment of a semiconductor die stack including a bond crack detection structure according to an example embodiment of the present disclosure (similar to Embodiment 3 previously described with reference to FIGS. 2A-2C). FIG. 7A is a top view and FIG. 7B is a cross sectional view. According to this example embodiment, the bond crack detection structure includes all of the features previously described with reference to FIGS. 2A-2C which will not be repeated here. In addition, Automated Test Equipment (ATE) 401 provides automated V-I testing of the semiconductor stacked and bonded structure to determine if any bonding interface cracks exist. Independent IMD layer 114 and first level interconnect 115, and IMD layer 124 and first level interconnect 125 provide external electrical connections of the bond crack detection structure to the ATE 401.

Referring to FIGS. 8A-8C, illustrated are further operational and design details associated with a bond crack detection structure according to an example embodiment of the present disclosure (Embodiment 2).

Referring to FIG. 8A, illustrated is a top view of bond crack detection structures, including a first crack detection region 311 (top) and a second crack detection region (bottom) as they relate to bond crack detection sensitivity and finger count.

Specifically, as shown, as the number of metal bonding pad finger chains increases, the crack detection region 311 increases in size and as a result, the bonding crack detection sensitivity of the bond crack detection structure increases. For comparison, the smaller detection region 311 of the top FIG. 8A includes 1 FC for conductor A (metal bonding pads 210 and 110 (not shown) and 1 FC for conductor B (metal bonding pad 220 and 120 (not shown). The bottom FIG. 8A includes an FC of 3 for conductor A (bonding metal pads 210 and 110 (not shown)) and a FC of 2 for conductor B (metal bonding pad 220 and 120 (not shown).

Referring to FIG. 8B, illustrated is a top view of bond crack detection structures, including a first crack detection region 311 (top) and a second crack detection region (bottom) as they relate to bond crack detection sensitivity and finger count/BPM pitch (i.e. metal bonding pad width).

Specifically, as shown, as the ratio of FC/BPM pitch increases, the density of coverage of the crack detection region 311 increases, thereby increasing the bonding crack detection sensitivity of the bond crack detection structure. In other words, as the density of coverage of the crack detection region 311 increases, the minimum detectable crack length is reduced, thereby providing for detection of smaller crack relative to a larger density of coverage of the crack detection region 311 (top FIG. 8B)

For comparison, the detection region 311 of the top FIG. 8B includes 1 FC for conductor A (metal bonding pads 210 and 110 (not shown) and 1 FC for conductor B (metal bonding pad 220 and 120 (not shown). The bottom FIG. 8B includes a FC of 1 for conductor A (bonding metal pads 210 and 110 (not shown)) and a FC of 1 for conductor B (metal bonding pad 220 and 120 (not shown). However, the metal bonding pad 210 and 220 (also 110 and 120 (not shown)) spacing width (i.e. minimum detectable length) in the embodiment of the bottom FIG. 1s less than (i.e. closer) than the metal bonding pad 210 and 220 (also 110 and 120 (not shown)) spacing width (i.e. minimum detectable length) in the embodiment of the top FIG. 8B. In other words the bonding pad pitch BPMPITCHx2 is less than bonding pad pitch BPMPITCHx1. The BPM pitch BPMPITCHy1 and BPMPITCHy2 are equal for both the top and bottom FIGURES.

According to an example embodiment, the BPM pitch in the x and y directions is 1-100 um. Alternatively, the BPM pitch in the x direction is in the range of 0.001% to 10% of the die or chip width, and the BPM pitch in the y direction is in the range of 0.001% to 10% of the die or chip height.

According to an example embodiment, the BPM count is the range of 1-1975 BPMs. Alternatively, the BPM count is in the range of 1 to chip width/BPM pitch in both the y and x directions.

Other factors that affect the sensitivity of the bonding crack detection structure include the thickness of the metal bonding pads in the vertical direction, which would be the z axis (out of the paper) in FIGS. 8A and 8B. As the BPM thickness increases, the sensitivity of the bonding crack detection structure increases because more vertical area of the IMD layer 202 is covered by the conductors A and B as previously described. BPM or metal bonding pad thickness is equivalent and further illustrated as VDRh 311 in FIG. 8C. According to an example embodiment, the BPM thickness, or alternatively BPM height, is in the range 1-100% of the thickness of IMD layer(s) 102 and/or 202 as shown in FIG. 8C.

Referring to FIG. 8C, illustrated is a top view of bond crack detection structures, including a first crack detection region 311 (top) and a second crack detection region (bottom) as they relate to bond crack detection sensitivity and metallization stacking, e.g. routing of conductor A and conductor B through the length of IMD 202, e.g. to the Si BEOL metal layer.

Specifically, as shown, as the number of metallization stacks increase, the vertical detection region (VDRh) is extended vertically and the bonding crack detection structure increases in sensitivity. As shown in the bottom FIG. 8C, the metallization stacks are formed by a series of connected vias 212A, 212B, 212C/213A, 213B, 213C (conductor A) and metallization layers 222A, 222B, 222C/223A, 223B, 223C (conductor B), thereby vertically extending the vertical bonding crack detection region to the length of the IMD layer 202 TD, relative to the vertical detection region shown in the top FIG. 8C, which is less than TDL. The extended vertical detection region of the bottom FIG. 8C detects a second bonding crack 63, not detected in the relatively shorter vertical crack detection region of the top FIG. 8C.

Other design considerations associated with the disclosed bonding crack detection structure include bonding metal pad shape, which can be circular, oval and/or polygonal. Placement of the bond crack detection structures over the area of the die or wafer also impacts effectiveness of the bond crack detection. Some suitable locations for the bond crack detection structures are described next.

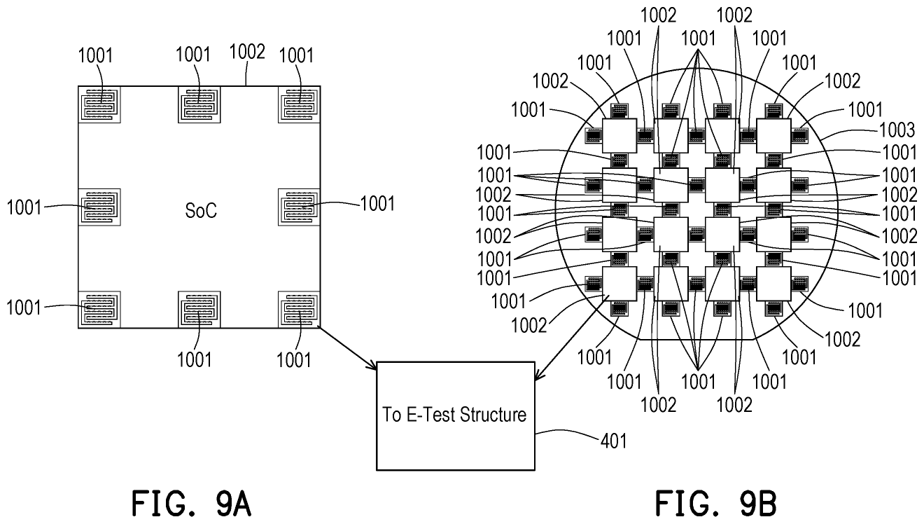

Referring to FIG. 9A, illustrated is a plurality of bond crack detection structures integrated into a SoC (System on a Chip) package according to an example embodiment of the present disclosure, and referring to FIG. 9B, illustrated is a plurality of bond crack detection structures integrated into a wafer including multiple SoCs according to an example embodiment of the present disclosure.

As shown in FIG. 9A, according to this example embodiment, a plurality of bonding crack detection structures 1001, as previously described, are formed on the outside, or just inside, peripheral areas of the SoC 1002 that do not include functional MOSFETs or other functional circuitry of the SoC 1002. By locating the bonding crack detection structure to the locations shown, the overall likelihood of detecting a bonding crack can be improved because bonding cracks can be more likely to happen at these locations. In addition, the location of the bonding crack detection structures 1001 at these peripheral locations can be practical for reasons related to the location of the SoC in the center area of the semiconductor die. However, it is to be understood that the locations of the bonding crack detection structures are not limited to the locations shown in FIG. 9A, and can be located in other areas of the SoC 1002.

After forming SoC 1002 including the bonding crack detection structures 1001, the SoC die 1001 is E-tested 401 to determine if any bonding crack exist as previously described.

As shown in FIG. 9B, according to this example embodiment, the wafer or die is a full wafer 1003 and an array of integrated circuits (ICs) 1002 are fabricated on the wafer 1003. Here, a plurality of bonding crack detection structures 1001, as previously described, are formed on the outside peripheral areas of a plurality of the ICs 1002 formed on a wafer 1003. In some embodiments, the bonding crack detection structures 1001 are disposed in scribe lines running between the ICs 1002 (where the scribe lines are destined to be the cut lines where the wafer 1003 will be cut when the individual ICs 1002 are singulated to form IC dies). By locating the bonding crack detection structure to the locations shown, the overall likelihood of detecting a bonding crack can be improved because bonding cracks can be more likely to happen at these locations. In addition, the location of the bonding crack detection structures 1001 at these peripheral locations can be practical for reasons related to the forming of the bonding crack detection structures 1001 in the scribe lines of the wafer 1003,

After forming wafer 1003, including the bonding crack detection structures 1001, the wafer 1003 is E-tested 401 to determine if any bonding crack exist as previously described.

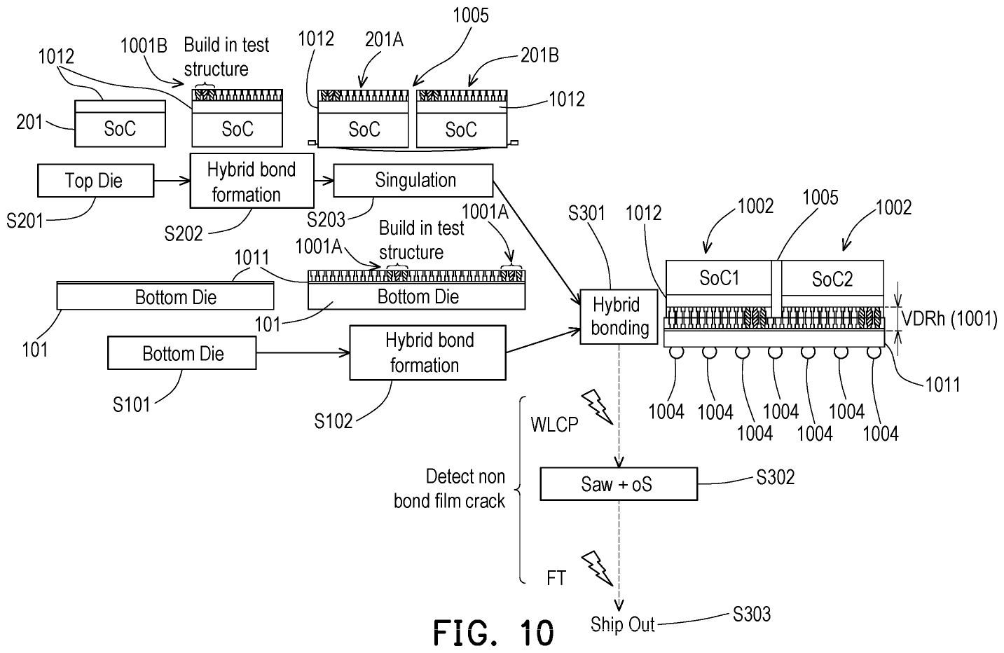

Referring to FIG. 10, illustrated is a process for fabricating a semiconductor die stack including multiple bond crack detection structures according to an example embodiment of the present disclosure, in context of an overall semiconductor fabrication workflow shown at a diagrammatic high level. In this example, die-to-wafer bonding is performed.

Initially, at S101, a bottom die 101 is fabricated and a hybrid bond formation process S102 is used to attach and bond one or more bond crack detection structure portions 1001A to a metallization layer 1011 of the bottom die 101.

Independently from steps S101 and S102, at step S201, a top die 201 is fabricated and processed to include a SoC and metallization layer 1012. Then, a hybrid bond formation process S202 is used to attach and bond one or more bond crack detection structure portions 1001B to the top die 201. Next, at step S203, a die singulation process is used to isolate, i.e. separate, a plurality of SoC dies (201A and 201B) and associated bonding crack detection structures 1001 with a trench or void 1005.

Next, at step S301, a hybrid bonding process is used to bond the bottom die 101 to the top die 201, and deposit a filler material, e.g. polymer, into the isolation region 1005. It is during this bonding process that the complete bonding crack detection structure 1001 is formed, resulting in a bonding crack detection vertical detection region length of VDRh. In addition, further processing includes the forming of a plurality of first level interconnects 1004 within IMD layer 1011.

Next, at step S302, a Saw, i.e. die singulation, on the substrate (oS) is performed and the chips are packaged for shipping S303. Advantageously, any time after step S301, the bonding crack detection structure(s) 1001 can be tested as previously described. For example, the singulated dies can be crack tested during a Wafer Level Chip Package (WLCP) Test phase and/or a Final Test (FT).

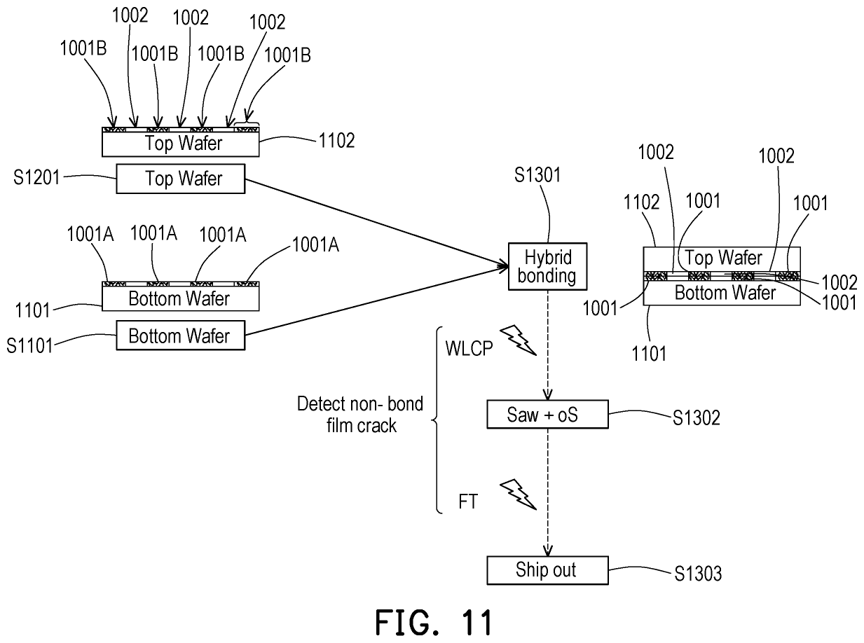

Referring to FIG. 11, illustrated is a process for fabricating a semiconductor wafer stack including multiple bonding crack detection structures 1001 according to an example embodiment of the present disclosure, in context of an overall semiconductor fabrication workflow shown at a diagrammatic high level. In this example, wafer-to-wafer bonding is performed.

Initially, at S1101, bottom wafer 1101 is fabricated and a hybrid bond formation process is used to attach and bond one or more bond crack detection structure portions 1001A to a metallization layer of the bottom wafer 1101.

Independently from step S1101, at step S1201, a top wafer 1102 is fabricated and processed to include a plurality of SoCs 1002 and attach and bond one or more bond crack detection structure portions 1001B to the top wafer 1102.

Next, at step S1301, a hybrid bonding process is used to bond the bottom wafer 1101 to the top wafer 1102. It is during this bonding process that the complete bonding crack detection structures 1001 are formed as discussed with reference to FIG. 10.

Next, at step S1302, a Saw, i.e. die singulation, on the substrate (oS) is performed and used to isolate, i.e. separate, a plurality of SoC dies (1002) and associated bonding crack detection structures 1001. Then the chips are packaged for shipping S1303. Any time after step S1301, the bonding crack detection structure(s) 1001 can be tested as previously described. For example, the singulated dies can be crack tested during a Wafer Level Chip Package (WLCP) Test phase and/or a Final Test (FT).

Provided below is another method of processing a semiconductor stack, such as a die or wafer, the die or wafer including a bonding crack detection structure as previously described.

The method of processing a semiconductor stack includes:
a) measuring an electrical characteristic of a bonding crack detection structure disposed at an interface between a first semiconductor wafer or die of the semiconductor stack and a second semiconductor wafer or die of the semiconductor stack that is bonded to the first semiconductor wafer or die of the semiconductor stack, the bonding crack detection structure including:
a first conductor comprising a first set of metal bonding bumps of the first semiconductor wafer or die and a third set of metal bonding bumps of the second semiconductor wafer or die which are bonded with the first set of metal bonding bumps of the first semiconductor wafer or die, and a second conductor comprising a second set of metal bonding bumps of the first semiconductor wafer or die and a fourth set of metal bonding bumps of the second semiconductor wafer or die which are bonded with the second set of metal bonding bumps of the first semiconductor wafer or die, wherein the first conductor and the second conductor are electrically isolated from each other in the absence of a bonding crack;
b) determining a bonding crack is not present at the interface between first and second semiconductor wafers or dies of the semiconductor stack based on the measured electrical characteristic of the bonding crack detection structure, including but not limited to electrical current flowing between the first conductor and the second conductor in response to a voltage applied across the first and second conductors; and
c) in response to the determination that a bonding crack is not present at the interface between first and second semiconductor wafers or dies of the semiconductor stack, dicing the semiconductor stack.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the disclosed bond crack detection structure prevents time consuming physical failure analysis to determine if a bonded stacked die and/or stacked wafer has failed due to one or more bonding interface cracks.

In the following, some further embodiments are described.

In a nonlimiting illustrative embodiment, a semiconductor structure comprising: a first semiconductor die including a first bonding crack detection structure portion, the first bonding crack detection structure portion including a first set of metal bond pads operatively connected to a bonding interface side of the first semiconductor die and a second set of metal bond pads operatively connected to the bonding interface side of the first semiconductor die, the second set of metal bond pads electrically isolated from the first set of metal bond pads; a second semiconductor die bonded to the first semiconductor die, the second semiconductor die including a second bonding crack detection structure portion that is bonded to the first bonding crack detection structure portion, the second bonding crack detection structure portion including a third set of metal bond pads operatively connected to a bonding interface side of the second semiconductor die and a fourth set of metal bond pads operatively connected to the bonding interface side of the second semiconductor die, the fourth set of metal bond pads electrically isolated from the third set of metal bond pads, wherein the first bonding crack detection structure portion and the second bonding crack detection structure portion are bonded together to form a bonding crack detection structure in which the first set of metal bond pads and the third set of metal bond pads are electrically connected together, and the second set of metal bond pads and the fourth set of metal bond pads are electrically connected together.

In another nonlimiting illustrative embodiment, a semiconductor structure comprising: a first semiconductor wafer including a first bonding crack detection structure portion, the first bonding crack detection structure portion including a first set of metal bond pads operatively connected to a bonding interface side of the first semiconductor wafer and a second set of metal bond pads operatively connected to the bonding interface side of the first semiconductor wafer, the second set of metal bond pads electrically isolated from the first set of metal bond pads; a second semiconductor wafer bonded to the first semiconductor wafer, the second semiconductor wafer including a second bonding crack detection structure portion that is bonded to the first bonding crack detection structure portion, the second bonding crack detection structure portion including a third set of metal bond pads operatively connected to a bonding interface side of the second semiconductor wafer and a fourth set of metal bond pads operatively connected to the bonding interface side of the second semiconductor wafer, the fourth set of metal bond pads electrically isolated from the third set of metal bond pads, wherein the first bonding crack detection structure portion and the second bonding crack detection structure portion are bonded together to form a bonding crack detection structure in which the first set of metal bond pads and the third set of metal bond pads are electrically connected together, and the second set of metal bond pads and the fourth set of metal bond pads are electrically connected together.

In another nonlimiting illustrative embodiment, a method of processing a semiconductor stack, the method comprising: measuring an electrical characteristic of a bonding crack detection structure disposed at an interface between a first semiconductor wafer or die of the semiconductor stack and a second semiconductor wafer or die of the semiconductor stack that is bonded to the first semiconductor wafer or die of the semiconductor stack, the bonding crack detection structure including: a first conductor comprising a first set of metal bonding bumps of the first semiconductor wafer or die and a third set of metal bonding bumps of the second semiconductor wafer or die which are bonded with the first set of metal bonding bumps of the first semiconductor wafer or die, and a second conductor comprising a second set of metal bonding bumps of the first semiconductor wafer or die and a fourth set of metal bonding bumps of the second semiconductor wafer or die which are bonded with the second set of metal bonding bumps of the first semiconductor wafer or die, wherein the first conductor and the second conductor are electrically isolated from each other in the absence of a bonding crack; determining a bonding crack is not present at the interface between first and second semiconductor wafers or dies of the semiconductor stack based on the measured electrical characteristic of the bonding crack detection structure; and in response to the determination that a bonding crack is not present at the interface between first and second semiconductor wafers or dies of the semiconductor stack, dicing the semiconductor stack.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure comprising:
a first semiconductor die or wafer including a first bonding crack detection structure portion, the first bonding crack detection structure portion including a first set of metal bond pads operatively connected to a bonding interface side of the first semiconductor die or wafer and a second set of metal bond pads operatively connected to the bonding interface side of the first semiconductor die or wafer, the second set of metal bond pads electrically isolated from the first set of metal bond pads;
a second semiconductor die or wafer bonded to the first semiconductor die or wafer, the second semiconductor die or wafer including a second bonding crack detection structure portion that is bonded to the first bonding crack detection structure portion, the second bonding crack detection structure portion including a third set of metal bond pads operatively connected to a bonding interface side of the second semiconductor die or wafer and a fourth set of metal bond pads operatively connected to the bonding interface side of the second semiconductor die or wafer, the fourth set of metal bond pads electrically isolated from the third set of metal bond pads,
wherein the first bonding crack detection structure portion and the second bonding crack detection structure portion are bonded together to form a bonding crack detection structure in which the first set of metal bond pads and the third set of metal bond pads are electrically connected together, and the second set of metal bond pads and the fourth set of metal bond pads are electrically connected together.

2. The semiconductor structure according to claim 1, wherein the bonding crack detection structure comprises a capacitor including:
a first conductor of the capacitor comprising the first set of metal bond pads and the third set of metal bond pads which are electrically connected together; and
a second conductor of the capacitor comprising the second set of metal bond pads and the fourth set of metal bond pads which are electrically connected together; and
an insulator of the capacitor comprising a gap between the first conductor of the capacitor and the second conductor of the capacitor.

3. The semiconductor structure according to claim 1, wherein the bonding crack detection structure comprises an interdigitated capacitor.

4. The semiconductor structure according to claim 3, wherein the interdigitated bonding crack detection structure further comprises:
the first set of metal bond pads arranged as a plurality of electrically connected first set of metal bond pad fingers extending parallel to each other, each of the first set of metal bond pad fingers laterally offset from each other by a finger lateral offset distance, and the second set of metal bond pads arranged as a plurality of electrically connected second set of metal bond pad fingers extending parallel to each other, each of the second set of metal bond pad fingers laterally offset by the finger lateral offset distance and the second set of metal bond pad fingers interdigitated between and/or adjacent the first set of metal bond pad fingers; and
the third set of metal bond pads arranged as a plurality of electrically connected third set of metal bond pad fingers extending parallel to each other, each of the third set of metal bond pad fingers laterally offset from each other by the finger lateral offset distance, and the fourth set of metal bond pads arranged as a plurality of electrically connected fourth set of metal bond pad fingers extending parallel to each other, each of the fourth set of metal bond pad fingers laterally offset by the finger lateral offset distance and the fourth set of metal bond pad fingers interdigitated between and/or adjacent the third set of metal bond pad fingers.

5. The semiconductor structure according to claim 4, wherein bond pad vias (BPV) interconnect the first, second, third, and fourth sets of metal bond pad fingers to their respective metal bond pads.

6. The semiconductor structure according to claim 1, wherein
the bonding crack detection structure is formed in a first intermetal dielectric (IMD) layer of the first semiconductor die or wafer and a second IMD layer associated with the second semiconductor die or wafer;
each of the metal bonding pads of the first, second, third, and fourth sets of metal bonding pads has a BPM thickness associated with a thickness of a sidewall of the metal bond pad, the BPM thickness of each metal bond pad included in the first IMD layers equal to 1 up to 100% of a height of the first IMD layer, and the BPM thickness of each metal bond pad included in the second IMD layer equal to 1 to 100% of a height of the second IMD layer; and
each of the first, second, third and fourth sets of metal bond pads is defined as having a BPM count and a BPM pitch, the BPM pitch associated with the spacing of the metal bond pads, and the BPM count equal to 1 up to a width of the semiconductor structure/BPM pitch.

7. The semiconductor structure according to claim 1, wherein the first semiconductor die or wafer includes a first intermetal dielectric (IMD) electrically connected to the first set of metal bond pads, and a second IMD electrically connected to a second set of metal bond pads, the second IMD electrically isolated from the first IMD, and the first IMD and the second IMD each connected to first level interconnects configured to operatively connect to a leakage current testing unit to measure a leakage current and detect bonding cracks based on the measured leakage current.

8. The semiconductor structure according to claim 1, wherein the metal bond pads are circular shaped, oval shaped or polygonal shaped.

9. The semiconductor structure according to claim 1, wherein the bonding crack detection structure is located along one or more edges of the semiconductor structure, or one or more edges of the first semiconductor die or wafer and the second semiconductor die or wafer.

10. A semiconductor structure comprising:
a first semiconductor wafer including a first bonding crack detection structure portion, the first bonding crack detection structure portion including a first set of metal bond pads operatively connected to a bonding interface side of the first semiconductor wafer and a second set of metal bond pads operatively connected to the bonding interface side of the first semiconductor wafer, the second set of metal bond pads electrically isolated from the first set of metal bond pads;
a second semiconductor wafer bonded to the first semiconductor wafer, the second semiconductor wafer including a second bonding crack detection structure portion that is bonded to the first bonding crack detection structure portion, the second bonding crack detection structure portion including a third set of metal bond pads operatively connected to a bonding interface side of the second semiconductor wafer and a fourth set of metal bond pads operatively connected to the bonding interface side of the second semiconductor wafer, the fourth set of metal bond pads electrically isolated from the third set of metal bond pads,
wherein the first bonding crack detection structure portion and the second bonding crack detection structure portion are bonded together to form a bonding crack detection structure in which the first set of metal bond pads and the third set of metal bond pads are electrically connected together, and the second set of metal bond pads and the fourth set of metal bond pads are electrically connected together.

11. The semiconductor structure according to claim 10, wherein the bonding crack detection structure comprises a capacitor including:
a first conductor of the capacitor comprising the first set of metal bond pads and the third set of metal bond pads which are electrically connected together; and
a second conductor of the capacitor comprising the second set of metal bond pads and the fourth set of metal bond pads which are electrically connected together.

12. The semiconductor structure according to claim 10 wherein the wherein the bonding crack detection structure comprises an interdigitated capacitor.

13. The semiconductor structure according to claim 12, wherein the interdigitated bonding crack detection structure further comprises:
the first set of metal bond pads arranged as a plurality of electrically connected first set of metal bond pad fingers extending parallel to each other, each of the first set of metal bond pad fingers laterally offset from each other by a finger lateral offset distance, and the second set of metal bond pads arranged as a plurality of electrically connected second set of metal bond pad fingers extending parallel to each other, each of the second set of metal bond pad fingers laterally offset by the finger lateral offset distance and the second set of metal bond pad fingers interdigitated between and/or adjacent the first set of metal bond pad fingers; and
the third set of metal bond pads arranged as a plurality of electrically connected third set of metal bond pad fingers extending parallel to each other, each of the third set of metal bond pad fingers laterally offset from each other by the finger lateral offset distance, and the fourth set of metal bond pads arranged as a plurality of electrically connected fourth set of metal bond pad fingers extending parallel to each other, each of the fourth set of metal bond pad fingers laterally offset by the finger lateral offset distance and the fourth set of metal bond pad fingers interdigitated between and/or adjacent the third set of metal bond pad fingers.

14. The semiconductor structure according to claim 13, wherein bond pad vias (BPV) interconnect the first, second, third, and fourth sets of metal bond pad fingers to their respective metal bond pads.

15. The semiconductor structure according to claim 10, wherein
the bonding crack detection structure is formed in a first intermetal dielectric (IMD) layer of the first semiconductor wafer and a second IMD layer associated with the second semiconductor wafer;
each of the metal bonding pads of the first, second, third, and fourth sets of metal bonding pads has a BPM thickness associated with a thickness of a sidewall of the metal bond pad, the BPM thickness of each metal bond pad included in the first IMD layers equal to 1 up to 100% of a height of the first IMD layer, and the BPM thickness of each metal bond pad included in the second IMD layer equal to 1 to 100% of a height of the second IMD layer; and
each of the first, second, third and fourth sets of metal bond pads is defined as having a BPM count and a BPM pitch, the BPM pitch associated with the spacing of the metal bond pads, and the BPM count equal to 1 up to a width of the semiconductor structure/BPM pitch.

16. The semiconductor structure according to claim 10, wherein the first semiconductor wafer includes a first intermetal dielectric (IMD) electrically connected to the first set of metal bond pads, and a second IMD electrically connected to a second set of metal bond pads, the second IMD electrically isolated from the first IMD, and the first IMD and the second IMD each connected to first level interconnects configured to operatively connect to a leakage current testing unit to measure a leakage current and detect bonding cracks based on the measured leakage current.

17. The semiconductor structure according to claim 10, wherein the metal bond pads are circular shaped, oval shaped or polygonal shaped.

18. The semiconductor structure according to claim 10, wherein the bonding crack detection structure is located along one or more edges of the semiconductor structure, one or more edges of a plurality of dies located on the first semiconductor wafer and second semiconductor wafer, or in one or more scribe lines of the first semiconductor wafer and second semiconductor wafer.

19. A method of processing a semiconductor stack, the method comprising:
measuring an electrical characteristic of a bonding crack detection structure disposed at an interface between a first semiconductor wafer or die of the semiconductor stack and a second semiconductor wafer or die of the semiconductor stack that is bonded to the first semiconductor wafer or die of the semiconductor stack, the bonding crack detection structure including:
a first conductor comprising a first set of metal bonding bumps of the first semiconductor wafer or die and a third set of metal bonding bumps of the second semiconductor wafer or die which are bonded with the first set of metal bonding bumps of the first semiconductor wafer or die, and
a second conductor comprising a second set of metal bonding bumps of the first semiconductor wafer or die and a fourth set of metal bonding bumps of the second semiconductor wafer or die which are bonded with the second set of metal bonding bumps of the first semiconductor wafer or die,
wherein the first conductor and the second conductor are electrically isolated from each other in the absence of a bonding crack;
determining a bonding crack is not present at the interface between first and second semiconductor wafers or dies of the semiconductor stack based on the measured electrical characteristic of the bonding crack detection structure; and
in response to the determination that a bonding crack is not present at the interface between first and second semiconductor wafers or dies of the semiconductor stack, dicing the semiconductor stack.

20. The method of claim 19, wherein the electrical characteristic is an electrical current flowing between the first conductor and the second conductor in response to a voltage applied across the first and second conductors.
